(19) United States
(12) Patent Application Publication
(10) Pub. No.: US 2014/0003455 A1
(43) Pub. Date: Jan. 2, 2014

(54) DIODE-PUMPED SOLID STATE LASER

(71) Applicant: QIOPTIQ PHOTONICS LTD., Southampton (GB)

(72) Inventor: Tibor Jozsef Bereczki, Southampton (GB)

(73) Assignee: QIOPTIQ PHOTONICS LTD., Southampton (GB)

(21) Appl. No.: 13/929,604

(22) Filed: Jun. 27, 2013

(30) Foreign Application Priority Data
Jul. 2, 2012 (GB) 1211706.5

(51) Int. Cl. H01S 5/00

(52) U.S. Cl. CPC H01S 5/0092
USPC 372/22; 29/592.1

(57) ABSTRACT

A monolithic laser cavity 1 for use in a diode-pumped solid state laser comprises a pair of mirrors 4, 5, forming input and output ends of the cavity 1. Arranged between the mirrors 4, 5 is an amplifying element 6, a birefringent element 7, an optically isotropic element 8, and a birefringent nonlinear optical element 9. The birefringent element 7 is arranged at an angle to the optical axis of the cavity 1 such that parallel surfaces of the birefringent element 7 act as polarising elements, and such that the birefringent element 7 acts as a first Lyot filter within the laser cavity 1, and the angled birefringent element 7, the birefringent nonlinear optical element 9 and cavity mirror 5 following the birefringent nonlinear optical element 9 together act as a second Lyot filter within the laser cavity 1, thereby providing wavelength selection within the laser cavity 1.

### BACKGROUND

The technology described herein relates to diode-pumped, solid state lasers and in particular to such lasers which use intra-cavity second harmonic generation (SHG) and that can provide single frequency laser emission.

As is known in the art, diode-pumped solid state (DPSS) lasers are lasers in which a solid lasing gain (amplifying) medium, such as a ruby or a neodymium-doped YAG (yttrium aluminium garnet) crystal, is pumped with a laser diode. Advantages of DPSS lasers include their relative compactness and efficiency as compared to other types of laser.

A typical DPSS SHG laser will use a relatively powerful 808 nm IR diode laser to pump an Nd:YAG laser (or other gain material) crystal arranged inside an optical cavity (resonator) to produce light from the spectral transitions of the neodymium ion. This light is then usually passed through a non-linear optical crystal, such as a KTP (Potassium Titanyl Phosphate, KTiOPO4) or BiBO (Bismuth Triborate, BiB3O6) crystal, to frequency double the light produced by the Nd:YAG crystal to provide output light in the visible spectrum. An Nd:YAG DPSS SHG laser is typically used to produce either green output light of 532 nm (by frequency doubling the 1064 nm wavelength light from the main spectral transition of the neodymium ions), or blue output light at 473 nm (by frequency doubling 946 nm wavelength light from a non-principal spectral line of the neodymium ions).

One issue with DPSS lasers is the selection of the wavelength to be used from the range of wavelengths generated by the Nd:YAG (or other) gain material when it is pumped by the diode laser. FIG. 8 shows some of the multiple Nd:YAG energy levels and transitions. Wavelength selection is usually achieved by using dichroic mirrors, which as is known in the art, reflect some wavelengths of light while transmitting others. Wavelength selection (filtering) may additionally and/or alternatively be achieved by including an optical filter within the laser's optical cavity. A common form of optical filter that is used for this purpose is a so-called Lyot filter which uses a birefringent element between two polarising elements to form a wavelength filter. It is also known to use two Lyot filters within the laser cavity to provide improved wavelength selection (filtering).

The Applicants believe there remains scope for improvements to diode-pumped solid state lasers.

### BRIEF DESCRIPTION OF THE DRAWINGS

A number of embodiments of the technology described herein will now be described by way of example only and with reference to the accompanying drawings, in which:

FIGS. 1 to 3 show schematically the principal design features of a first embodiment of the laser cavity of the technology described herein;

FIG. 4 shows schematically the path of the light rays in the laser cavity of the first embodiment of the technology described herein;

FIGS. 5, 6 and 7 show schematically further embodiments of the technology described herein;

FIG. 8 shows some important Nd:YAG energy levels and transitions; and

FIG. 9A shows schematically a top view and FIG. 9B shows schematically a side view of a laser constructed using the laser cavity of FIG. 1.

Like or similar reference numerals are used for like and similar components throughout the drawings.

### DETAILED DESCRIPTION

A first embodiment of the technology described herein comprises a monolithic laser cavity for use in a diode-pumped solid state laser, the laser cavity comprising:
a pair of mirrors, one mirror forming an input end of the cavity for receiving an input pump laser beam in use, and the other mirror forming an output end of the cavity from which the output laser beam produced by the cavity will exit the cavity in use;
and, arranged between the mirrors forming the ends of the cavity:
an amplifying element comprising a lasing gain material that can be pumped by a diode laser to generate a laser beam;
a birefringent element having two parallel surfaces arranged after the amplifying element;
an optically isotropic element arranged after the birefringent element; and
a birefringent nonlinear optical element arranged after the optically isotropic element for frequency doubling a laser beam generated by the amplifying element so as to generate a laser beam of a second harmonic wavelength; and wherein:
the birefringent element is arranged at an angle to the optical axis of the cavity such that the parallel surfaces of the birefringent element act as polarising elements, and such that the birefringent element will accordingly act as a first Lyot filter within the laser cavity, and the angled birefringent element, the birefringent nonlinear optical element and cavity mirror following the birefringent nonlinear optical element will together act as a second Lyot filter within the laser cavity, thereby to provide wavelength selection within the laser cavity.

The technology described herein also extends to a diode-pumped solid state laser comprising the laser cavity of the technology described herein.

Thus, a second embodiment of the technology described herein comprises a diode-pumped solid state laser comprising a diode laser and a monolithic laser cavity according to the first embodiment of the technology described herein, and wherein the diode laser and laser cavity are configured such that the diode laser can be used to pump the amplifying element of the laser cavity to thereby generate a laser beam output from the laser cavity.

The monolithic laser cavity (and diode-pumped solid state laser) of the technology described herein contains, as in conventional diode-pumped solid state lasers, an amplifying (gain) element that is to be pumped by a diode laser and a birefringent nonlinear optical element to produce a desired output laser beam using frequency doubling (second harmonic generation). It also includes optical filters in the form of Lyot filters to provide wavelength selection (filtering). However, in the technology described herein, the Lyot filters are provided by means of the combination of an angled (tilted) birefringent element and the birefringent nonlinear optical element.

As discussed above, a Lyot filter is constructed by sandwiching a birefringent element between two polarising elements. This is normally achieved by providing separate polarising elements on each side of a birefringent element. However, the Applicants have recognised that by arranging a birefringent element at an angle to the optical axis (i.e. by having a tilted birefringent element in the laser cavity), the parallel surfaces (faces) of that birefringent element can then themselves act as the polarising elements for a Lyot filter or filters, and the birefringent element itself when so arranged can act as a first Lyot filter. In addition, the combination of one of the surfaces of the birefringent element, the birefringent nonlinear optical element and the mirror at the output end of the cavity can act as a second Lyot filter.

This arrangement then facilitates the provision of two Lyot filters within the laser cavity (so as to then provide better wavelength selection (filtering)), but without the need to provide separate and additional polarising and/or birefringent elements. The effect of this then is that, as will be discussed further below, the laser cavity (and laser) of the technology described herein can be more compact as compared to prior art diode-pumped solid state lasers, and yet still achieve improved wavelength filtering (selection) by having two Lyot filters in the cavity.

The amplifying element can be formed of any suitable optically active gain material that can be pumped by a diode laser to generate a laser beam, such as Nd:YAG or Er:YAG. The gain material is in an embodiment optically isotropic (i.e. not birefringent), so that the generated light is non-polarised. In an embodiment the gain material is Nd:YAG.

As is known in the art, the amplifying element will typically generate a range of wavelengths. The first and second Lyot filters will then operate to (and should be configured to) select (filter) one of these wavelengths that will then be frequency-doubled to provide the output beam (wavelength) of the laser cavity. The wavelength that is selected (that is to be used) from the range of wavelengths may be any wavelength of the range, as desired. In an embodiment, the main (fundamental) wavelength of the amplifying element is selected, but this need not be the case. In an alternative embodiment, a non-principal (non-fundamental) wavelength generated by the amplifying element is selected.

The amplifying element is in an embodiment 1-10 mm long (along the direction of the optical axis of the cavity (Z)), 1-10 mm wide (X) and 1-10 mm high (Y). In an embodiment the amplifying element is 1-5 mm long, 1-5 mm wide and 1-5 mm high. In an embodiment, the amplifying element is 2 mm long, 3 mm wide and 3 mm high. The amplifying element may have any desired cross-section, such as a rectangular or circular cross-section.

The input face of the amplifying element is in an embodiment arranged to be perpendicular to the optical axis of the cavity (of the input pump diode laser beam).

The mirrors that form the ends of the laser cavity should be suitably arranged to form a laser cavity, as is known in the art. In an embodiment they are provided by appropriately treating the input and output faces, respectively, of the end elements of the cavity to provided suitably mirrored surfaces. In embodiments of the technology described herein, as will be discussed further below, the end elements of the cavity that accordingly in an embodiment have mirrored surfaces that form the mirrors at the ends of the cavity comprise the amplifying element or an optically isotropic element (where provided) at the input end of the cavity, and the output face of the birefringent nonlinear optical element at the output end of the cavity.

In an embodiment, the mirror at the input end of the cavity comprises a dichroic coating having high transmittance at the pump diode laser wavelength and high reflectivity at the selected wavelength of the range of wavelengths generated by the amplifying element. Similarly, the mirror at the output end of the cavity in an embodiment comprises a dichroic coating having high transmittance at the wavelength of the second harmonic light generated by the birefringent nonlinear optical element and high reflectivity at the selected wavelength of the range of wavelengths generated by the amplifying element.

The angled birefringent element can be any desired birefringent crystal, such as YV04 or quartz. In an embodiment it is quartz. The angled birefringent element may have any suitable form, as long as it has two parallel (i.e. plane-parallel) surfaces that may be arranged at an angle to the optical axis of the cavity such that they act as polarising elements. The parallel surfaces are in an embodiment parallel to a tolerance of ≦20 arcsec. The angled birefringent element may, for example, have the form of a parallelepiped or a rhomboid. However, in an embodiment, the birefringent element is in the form of a plate (e.g. a rectangular cuboid) wherein each pair of opposite surfaces are parallel. In an embodiment a plate is used for the angled birefringent element, as this can make manufacture more straightforward.

The birefringent element is in an embodiment arranged such that it forms Brewster interfaces with respect to the elements that it is arranged between (a Brewster interface is an interface at an angle (i.e. the Brewster angle, α_{Brewster}) between two media with refractive indices n₁ and n₂ such that the tangent of the angle is equal to the ratio of the indices (i.e. α_{Brewster}=tan(n₁/n₂)). Thus the birefringent element is in an embodiment tilted such that it lies at the respective Brewster angle (±0.1°) relative to the optical axis of the cavity (for the selected wavelength produced (generated) by the amplifying element).

As is known in the art, arranging the angled birefringent element to form Brewster interfaces will result in the surfaces of the angled birefringent element acting as polarising elements.

The thickness of the birefringent element may be selected as desired. As is known in the art, the thickness will control the free spectral range (FSR) of the Lyot filter formed by the angled birefringent element (the first Lyot filter) (and thus the range of wavelengths it passes) according to the equation:

$$FSR = \frac{{λ}^{2} sin {α}_{Brewster}}{Δ n \times l} \qquad ( 1 )$$

where λ is the wavelength, Δn is the birefringence of the birefringent element, and l is the thickness of the birefringent element.

The optically isotropic element arranged after the angled birefringent element can be any suitable optically isotropic element, such as YAG or fused silica. The element is optically isotropic so as to maintain the orientation of the polarisation of the light that passes through it. The optically isotropic element in an embodiment has a similar refractive index to and in an embodiment the same refractive index as, the amplifying element. (In an embodiment the angled birefringent element is sandwiched between (adjoined to) elements having similar or the same refractive index (i.e. in an embodiment there is material having the same refractive index on each side of the angled birefringent element).)

The optically isotropic element provides thermal isolation between the angled birefringent element and the birefringent nonlinear optical element so as to facilitate the ability to control the temperature of those two elements independently of each other in the monolithic structure (as will be discussed further below).

The optically isotropic element is in an embodiment 3-5 mm long (along the direction of the optical axis of the cavity (Z)).

The birefringent nonlinear optical element can be any suitable birefringent, nonlinear, optical crystal, such as KTP (KTiOPO4, Potassium Titanyl Phosphate), LBO (LiB₃O₅, Lithium Triborate), BBO (β-BaB₂O₄, Beta Barium Borate) or BiBO (BiB₃O₆, Bismuth Triborate) that can act as a second harmonic generator to provide a frequency-doubled, harmonic wavelength to be used as the output laser wavelength from the light generated by the amplifying element. In an embodiment it is a KTP crystal.

The size of the birefringent nonlinear optical element may be selected as desired. For example, in an embodiment it is 5-10 mm long, in an embodiment 5 mm long (along the direction of the optical axis of the cavity (Z)), 2-3 mm wide and 2-3 mm high. The length of the birefringent nonlinear optical element will control the FSR of the second Lyot filter.

The input and output faces of the nonlinear optical element are in an embodiment arranged to be perpendicular to the optical axis of the cavity (of the input pump diode laser beam).

In an embodiment, the polarisation axes both of the birefringent element and of the birefringent nonlinear optical element are oriented at 45° (±0.1°) with respect to the main polarisation axis of the laser cavity.

As discussed above, the arrangement of the elements within the laser cavity in the technology described herein is such that the birefringent element acts as a first Lyot filter and the birefringent element in combination with the birefringent nonlinear optical element acts as a second Lyot filter. One, and in an embodiment the first, Lyot filter is in an embodiment configured to be a coarser filter, and the other (in an embodiment the second) to be a finer filter. In an embodiment the coarser Lyot filter (in an embodiment the first Lyot filter) is configured to have a free spectral range of the order of magnitude of the width of the laser emission band of the amplifying element. The finer Lyot filter (in an embodiment the second Lyot filter) is accordingly in an embodiment configured to have a free spectral range that will select the desired wavelength (frequency) from that emission band (e.g. the fundamental wavelength generated by the amplifying element). Providing two Lyot filters in this manner can facilitate more sensitive and accurate filter tuning and wavelength selection (and make it, e.g., easier to select the desired wavelength for the laser).

In an embodiment, the diode-pumped solid state laser further comprises one or more temperature controllers coupled to the laser cavity. In an embodiment, the diode-pumped solid state laser comprises a first temperature controller coupled to the angled birefringent element, and a second temperature controller coupled to the nonlinear optical element. This then allows for the temperature of the angled birefringent element and of the nonlinear optical element to be controlled (and independently of each other). This can then be used to tune (independently of each other) the operation of the respective Lyot filters formed by these elements, for example to correct in use for any errors in the filter properties due to manufacturing tolerances.

In another embodiment, the diode-pumped solid state laser further comprises a third temperature controller coupled to the diode laser. This can then be used to control the temperature of the diode laser independently of the temperature of the laser cavity, and may be used to tune the operation of the diode laser (independently of the laser cavity).

Each temperature controller is in an embodiment coupled to its respective element of the diode-pumped solid state laser through a respective heat sink.

The laser cavity may comprise and only comprise (and in one embodiment does only comprise) the mirrors, the amplifying element, the angled birefringent element, the optically isotropic element, and the nonlinear optical element. In this case the cavity will consist of a mirror, followed by the amplifying element, followed by the angled birefringent element, followed by the optically isotropic element, followed by the nonlinear optical element, and finally, the other mirror forming the other end of the laser cavity. In this case, the angled (tilted) birefringent element (e.g. quartz plate) will be sandwiched between the amplifying element and the optically isotropic element.

However, it would also be possible for the cavity to include other elements, if desired. For example, an optically isotropic (and passive) element could be arranged between the mirror at the input and of the cavity and the amplifying element. This may be used to facilitate thermal management (e.g. cooling) of the gain material in use (which may then allow higher laser powers to be used). In these arrangements, the additional optically isotropic element can be any suitable such element, such as and in an embodiment an optically isotropic element of the form discussed above.

Thus, in another embodiment the laser cavity comprises (and only comprises): a mirror followed by an optically isotropic element, followed by the amplifying element, followed by the angled birefringent element, followed by an optically isotropic element, followed by the nonlinear optical element, followed by the mirror at the end of the cavity, with the angled birefringent element being sandwiched between the amplifying element and the second optically isotropic element.

Additionally or alternatively, the birefringent element could be sandwiched between two, in an embodiment identical, optically isotropic (and passive) elements. This would then allow the birefringent element to be bonded to similar, rather than dissimilar, materials when constructing the cavity, which may make manufacture easier. In this case it would be possible also to include an optically isotropic element between the mirror and the amplifying element at the start of the cavity, e.g., for cooling purposes, as discussed above.

Thus, in another embodiment, the laser cavity comprises (and only comprises): a mirror followed by the amplifying element, followed by an optically isotropic element, followed by the angled birefringent element, followed by an optically isotropic element, followed by the nonlinear optical element, followed by the mirror at the end of the cavity, with the angled birefringent element being sandwiched between the two optically isotropic elements. Similarly, in another embodiment, the laser cavity comprises (and only comprises): a mirror followed by an optically isotropic element, followed by the amplifying element, followed by an optically isotropic element, followed by the angled birefringent element, followed by an optically isotropic element, followed by nonlinear optical element, followed by the mirror at the end of the cavity, with the angled birefringent element again being sandwiched between the second two optically isotropic elements.

In an embodiment, apart from the faces of the angled birefringent element (and any corresponding face of an element that is adjacent to the angled birefringent element), all the other faces of the elements in the laser cavity are arranged to be perpendicular to the optical axis of the cavity. Thus, any element that is not adjacent to the angled birefringent element is in an embodiment in the form of a crystal with parallel faces. In an embodiment the parallel faces of the elements are parallel to a tolerance of ≦20 arcsec.

The laser cavity has a monolithic construction (structure), i.e. it has a solid, unbroken, and in an embodiment rigid, structure (it is one solid structure). The laser cavity can be constructed as desired in order to achieve this. In an embodiment the various elements are optically in contact with each other. In an embodiment, the elements of the cavity are joined together to form the monolithic laser (resonant) cavity. Such joining can be done using any suitable (optical) joining, e.g., bonding, technique. In an embodiment, except for the angled interfaces between the angled birefringent element and its immediately adjoining elements, every other element face and interface in the cavity will be (substantially) parallel to each other and to the faces of the other elements in the cavity (and perpendicular to the output direction of the laser beam). Thus, in an embodiment the laser cavity of the technology described herein is in the form of a monolithic, linear (i.e. where the laser beam is parallel to one axis almost everywhere in the cavity), resonant cavity. This allows a particularly compact and stable cavity to be constructed.

The laser cavity of the technology described herein can have a particularly compact shape and size. Indeed, the Applicants have found that the laser cavity can, and in an embodiment does have a size of not more than 25×20×25 mm (H×W×L), in an embodiment not more than 3×3×17 mm, and in an embodiment a size of 3×3×12 mm, 3×3×14.5 mm, or 3×3×17 mm (depending upon exactly how many elements are included in the cavity). This correspondingly then facilitates constructing a diode-pumped solid state laser having a size no greater than 40×40×80 mm (final manufactured footprint).

In an embodiment the cavity is further configured such that it can provide an optical output power 100 mW (in an embodiment 100-500 mW), a relatively high quality laser beam (in an embodiment a single longitudinal mode (SLM), low noise, polarised, circular beam), and is able to provide one or more of, and in an embodiment all of, the following output laser wavelengths: 553 nm, 556 nm, 558 nm, and 561 nm.

The diode laser that is used to pump the amplifying element of the laser cavity can be any suitable and desired such diode laser, such as an 808 nm IR diode laser (e.g. an 808 nm wavelength infra red GaAlAs diode laser). This pump laser should be arranged (in the diode-pumped solid state laser) such that its laser output can be input to the amplifying element in the laser cavity so as to “pump” that element to cause it to output light.

The technology described herein also extends to the manufacture of the laser cavity for a diode-pumped solid state laser of the technology described herein. Thus, another embodiment of the technology described herein comprises a method of manufacturing the laser cavity for use in a diode-pumped solid state laser of the technology described herein.

Similarly, another embodiment of the technology described herein comprises a method of constructing a monolithic laser cavity for use in a diode-pumped solid state laser, comprising:
providing a pair of mirrors to form the ends of the laser cavity, one mirror forming an input end of the cavity for receiving an input pump laser beam in use, and the other mirror forming an output end of the cavity from which the output laser beam produced by the cavity will exit the cavity in use; and
arranging between the mirrors forming the ends of the cavity:
an amplifying element comprising a lasing gain material that can be pumped by a diode laser to generate a laser beam;
a birefringent element having two parallel surfaces after the amplifying element;
an optically isotropic element after the birefringent element; and
a birefringent nonlinear optical element after the optically isotropic element for frequency doubling a laser beam generated by the amplifying element so as to generate a laser beam of a second harmonic wavelength; and further comprising:
arranging the birefringent element at an angle to the optical axis of the cavity such that the parallel surfaces of the birefringent element act as polarising elements, and such that the birefringent element will accordingly act as a first Lyot filter within the laser cavity, and the angled birefringent element, the birefringent nonlinear optical element and cavity mirror following the nonlinear optical element will together act as a second Lyot filter within the laser cavity, thereby to provide wavelength selection within the laser cavity; and
joining the elements of the cavity together so as to form a monolithic laser cavity.

The methods of these embodiments of the technology described herein can include and use any suitable and desired manufacturing techniques. Thus, for example, the individual elements making up the cavity may be individually formed and then appropriately bonded together, e.g., using epoxy-free optical bonding, to form a monolithic, linear, laser cavity of the form of the technology described herein. Similarly, the mirrors forming the ends of the cavity are in an embodiment formed by appropriately treating the input and output faces, respectively, of the end elements of the cavity to provide suitably mirrored surfaces. The cavity that is constructed, and its individual elements, can, and in an embodiment does, include any one or more or all of the features of the cavity discussed above.

It should be noted here that the Applicants believe that it had previously been considered that the construction of a monolithic laser cavity of the form of the technology described herein would have been difficult to achieve. However, the Applicants have found that cavity can be satisfactorily constructed using known manufacturing techniques, and, indeed, the technology described herein has arisen, at least in part, from this recognition that the construction of a laser cavity of the form of the technology described herein may be achievable, notwithstanding what was previously thought in this art.

The laser of the technology described herein can be used as desired and for any suitable and desired application, and the technology described herein accordingly also extends to the use of the laser of the technology described herein.

Thus, another embodiment of the technology described herein comprises a method of operating a diode-pumped solid state laser that has the form of the laser of the technology described herein, the method comprising:
using the diode laser to pump the amplifying element of the laser cavity so as to cause the amplifying element to generate light of a given wavelength; and
directing the laser light output from the cavity to a desired target.

When using the laser of the technology described herein, the laser can be operated in the normal manner for a diode-pumped solid state laser. In an embodiment, when using the laser of the technology described herein, the temperature of the angled birefringent element and of the nonlinear optical element is controlled (and independently of each other). This can then be used to tune (independently of each other) the operation of the respective Lyot filters formed by these elements, for example to correct in use for any errors in the filter properties due to manufacturing tolerances.

Thus, in an embodiment, the method of operating the diode-pumped solid state laser further comprises controlling the temperatures of the birefringent element and the nonlinear optical element independently of one another. In another embodiment the method further comprises controlling the temperature of the diode laser independently of the temperatures of the birefringent element and/or the nonlinear optical element.

The technology described herein can be used whenever and wherever a diode-pumped solid state laser source or source is required. As will be appreciated by those skilled in the art, it will find particular, albeit not exclusive, application in arrangements such as for laser-based fluorescent instruments, microscopy applications, etc. In these cases, as will be appreciated by those skilled in the art, the target or targets that the laser beam output is to be delivered to will comprise an optical instrument, such as a microscope.

The technology described herein accordingly also extends to an optical instrument or to an optical system comprising the diode-pumped solid state laser of the technology described herein, to a method of operating an optical instrument or optical system that includes the method of the technology described herein, and to the use of the system or methods of the technology described herein in or for or with an optical instrument or system. In an embodiment, the optical instrument or system comprises a microscope, a laser-based fluorescence instrument, a fluorescence imaging instrument, a scanning microscope, a confocal microscope, a total internal reflection fluorescence microscope (TIRF), a fluorescence correlation spectroscope (FCS), a flow cytometry instrument, an imaging cytometry instrument, a small animal or molecular imaging instrument, and/or a high content screening cellular instrument.

As will be appreciated by those skilled in the art, all of the above embodiments of the technology described herein can and in an embodiment do include any one or more or all of the features of the technology described herein, as appropriate.

The methods in accordance with the technology described herein may be implemented at least partially using software e.g. computer programs. It will thus be seen that when viewed from further embodiments the technology described herein comprises computer software specifically adapted to carry out the methods herein described when installed on a data processor, a computer program element comprising computer software code portions for performing the methods herein described when the program element is run on a data processor, and a computer program comprising code adapted to perform all the steps of a method or of the methods herein described when the program is run on a data processing system. The data processor may be a microprocessor system, a programmable FPGA (field programmable gate array), etc.

The technology described herein also extends to a computer software carrier comprising such software which when used to operate a laser system comprising a data processor causes in conjunction with said data processor said system to carry out the steps of the methods of the technology described herein. Such a computer software carrier could be a physical storage medium such as a ROM chip, CD ROM or disk, or could be a signal such as an electronic signal over wires, an optical signal or a radio signal such as to a satellite or the like.

It will further be appreciated that not all steps of the methods of the technology described herein need be carried out by computer software and thus from a further broad embodiment the technology described herein comprises computer software and such software installed on a computer software carrier for carrying out at least one of the steps of the methods set out herein.

The technology described herein may accordingly suitably be embodied as a computer program product for use with a computer system. Such an implementation may comprise a series of computer readable instructions either fixed on a tangible, non-transitory medium, such as a computer readable medium, for example, diskette, CD-ROM, ROM, or hard disk, or transmittable to a computer system, via a modem or other interface device, over either a tangible medium, including but not limited to optical or analogue communications lines, or intangibly using wireless techniques, including but not limited to microwave, infrared or other transmission techniques. The series of computer readable instructions embodies all or part of the functionality previously described herein.

Those skilled in the art will appreciate that such computer readable instructions can be written in a number of programming languages for use with many computer architectures or operating systems. Further, such instructions may be stored using any memory technology, present or future, including but not limited to, semiconductor, magnetic, or optical, or transmitted using any communications technology, present or future, including but not limited to optical, infrared, or microwave. It is contemplated that such a computer program product may be distributed as a removable medium with accompanying printed or electronic documentation, for example, shrink-wrapped software, pre-loaded with a computer system, for example, on a system ROM or fixed disk, or distributed from a server or electronic bulletin board over a network, for example, the Internet or World Wide Web.

As discussed above, the technology described herein relates to diode-pumped solid state lasers and in particular to a new design of lasing cavity for such a laser. A number of embodiments of the lasing cavity and laser of the technology described herein will now be described.

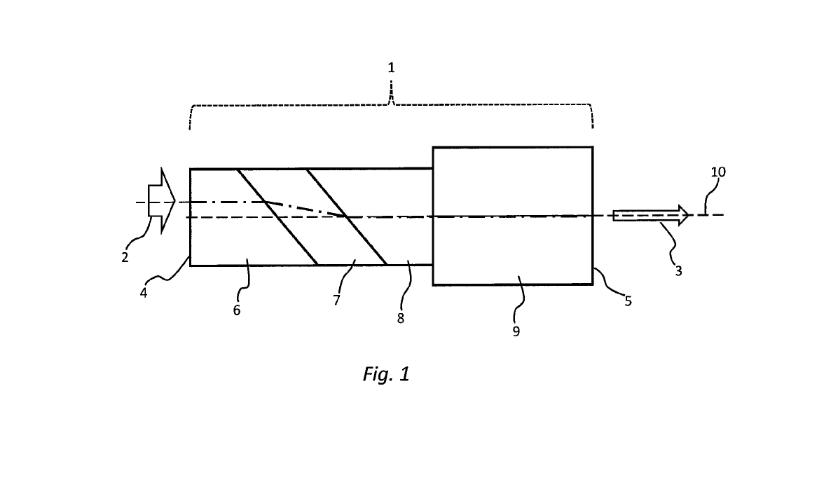

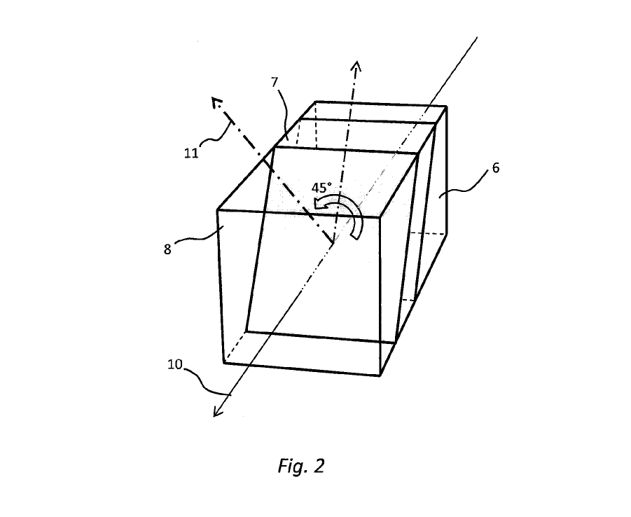

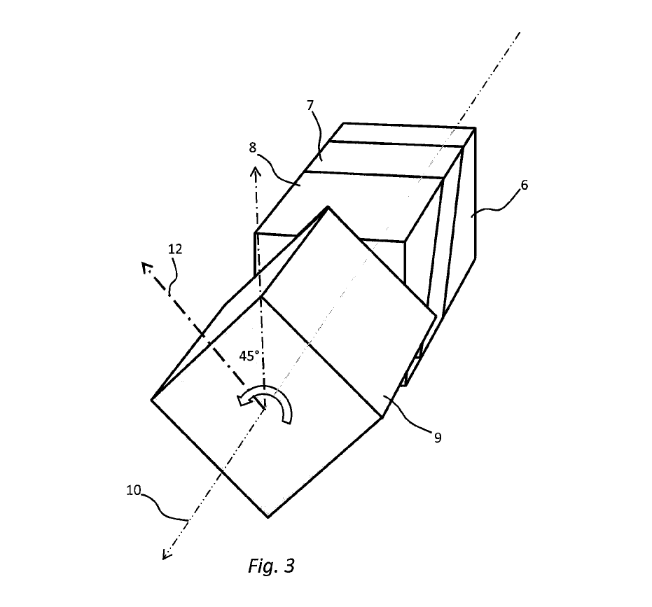

FIGS. 1 to 3 show schematically a first embodiment of the laser cavity of the technology described herein that shows the principal design features of the laser cavity design of the technology described herein. FIG. 1 is a longitudinal cross-sectional view of the cavity and FIGS. 2 and 3 show in more detail the arrangement and orientation of certain elements of the cavity.

As shown in FIG. 1, the cavity 1 has, as is known in the art, corresponding mirrors 4, 5 at each end that form the ends of the cavity. These mirrors are, in the present embodiment, formed by providing appropriately mirrored surfaces on the end elements of the cavity.

Arranged between the mirrors 4, 5 forming the ends of the cavity are a series of elements, which in the embodiment shown in FIGS. 1 to 3, comprise, in order relative to the input end of the cavity that receives the pump laser 2, a lasing gain (amplifying) element 6, an angled birefringent element 7, an optically isotropic element 8, and a birefringent nonlinear optical element 9. The input face of the amplifying element 6 and the output face of the birefringent nonlinear optical element 9 are, as shown in FIG. 1, arranged parallel to each other, and, as discussed above, are treated so as to form mirrored surfaces in order to form a resonant lasing cavity.

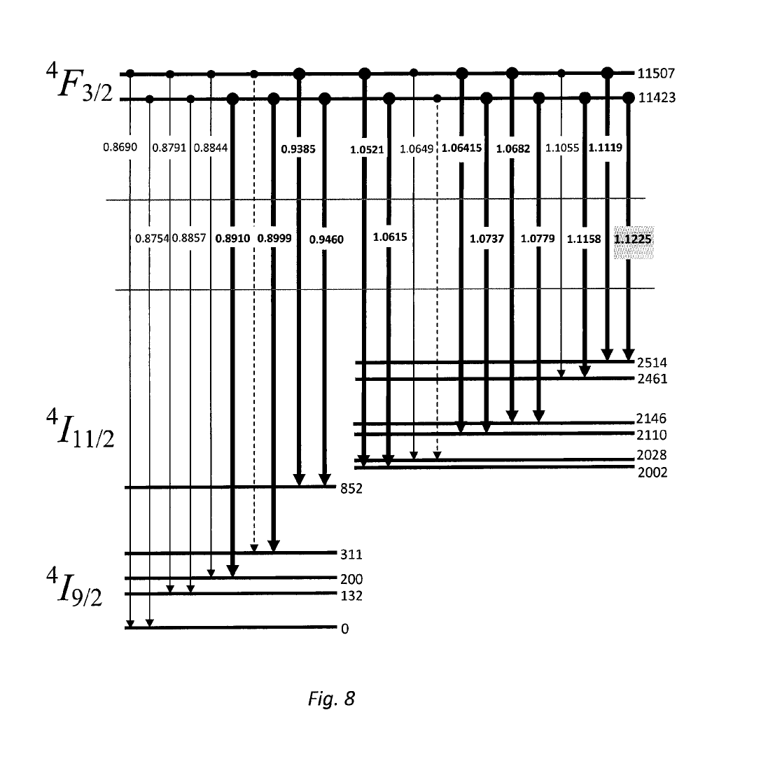

The lasing amplifying (gain) element 6 is in the present embodiment in the form of an Nd:YAG crystal which will, as is known in the art, generate a range of wavelengths of light according to the spectral transitions of the neodymium ions when stimulated with light 2 from a pump diode laser. The amplifying element 6 can be formed of any suitable optically active gain material that can be pumped by a diode laser to generate a non-polarised laser beam. FIG. 8 shows some of the multiple Nd:YAG energy levels and transitions.

The amplifying element 6 is in an embodiment 2 mm long (along the direction of the optical axis of the cavity), 3 mm wide and 3 mm high.

The input face of the amplifying element 6 is treated so as to constitute a flat mirror 4 that forms the input end of the cavity, as discussed above. It is arranged to be perpendicular to the main optical axis of the cavity and of the input pump diode laser beam 2.

The output face of the amplifying element 6 is cut (relative to the longitudinal axis of the cavity 1) at the Brewster angle calculated from the refractive index of the amplifying element 6 and the refractive index of the angled birefringent element 7 for the wavelength of the range of wavelengths that are generated by the amplifying element 6 that it is desired to use (select) to generate the output beam of the cavity (e.g. the main (fundamental) wavelength of the range of wavelengths).

The angled birefringent element 7 is in the form of a quartz plate having parallel surfaces. Other birefringent crystals, such as YV04 or sapphire, could be used, if desired. The thickness of the angled birefringent element 7 is selected in order to provide a desired FSR for the first Lyot filter.

As shown in FIG. 1, the angled birefringent element 7 is arranged at an angle relative to the main longitudinal optical axis of the cavity (the axis of the input pump laser beam 2) such that light travelling along that axis will be incident on the quartz plate at the Brewster angle. Thus, the faces of the angled birefringent element 7 are arranged (relative to the longitudinal axis of the cavity 1) at the Brewster angle (±1°) calculated from the refractive index of the amplifying element 6 and the refractive index of the angled birefringent element 7 for the selected wavelength of the range of wavelengths generated by the amplifying element 6 that is to be used. The effect of this then is that the faces of the angled birefringent element 7 will act as polarising elements.

The optically isotropic element 8 is in the present embodiment in the form of a YAG crystal. The optically isotropic element 8 thus has the same refractive index as the amplifying element 6. This keeps the laser beam orientation parallel to the optical axis of the cavity. (In an embodiment the angled birefringent element is sandwiched between (adjoined to) elements having the same refractive index (i.e. in an embodiment there is material having the same refractive index on each side of the angled birefringent element).)

The optically isotropic element 8 is optically isotropic so as to maintain the orientation of the polarisation of the light that passes through it. This element provides thermal insulation between the quartz plate 7 and the birefringent nonlinear optical element 9, so as to facilitate the ability to control the temperature of those two elements independently of each other (as will be discussed further below).

The optically isotropic element 8 is in an embodiment 3-5 mm long (along the direction of the optical axis of the cavity).

The input face of the optically isotropic element 8 is cut (relative to the longitudinal axis of the cavity 1) at the Brewster angle (±1°) calculated from the refractive index of the optically isotropic element 8 and the refractive index of the angled birefringent element 7 for the selected wavelength of the range of wavelengths generated by the amplifying element 6 that is to be used.

The output face of the optically isotropic element 8 is arranged to be perpendicular to the main optical axis of the cavity and of the input pump diode laser beam 2.

The birefringent nonlinear optical element 9 is a frequency doubling (second harmonic generator) crystal that will generate harmonic wavelengths from the light generated by the amplifying element 6 to provide an appropriate (e.g. visible) laser beam 3 for output from the cavity 1. The nonlinear optical element 9 can comprise any suitable birefringent non-linear optical medium (e.g. crystal), such as KTP (KTiOPO₄, Potassium Titanyl Phosphate), LBO (LiB₃O₅, Lithium Triborate), BBO (β-BaB₂O₄, Beta Barium Borate) or BiBO (BiB₃O₆, Bismuth Triborate), that is capable of frequency doubling the laser beam generated by the amplifying element 6 so as to generate an output laser beam 3 of a desired harmonic wavelength. In the present embodiment, the nonlinear optical element 9 is in the form of a KTP crystal.

The nonlinear optical element 9 is in an embodiment 5 mm long (along the direction of the optical axis of the cavity), 2-3 mm wide and 2-3 mm high.

The faces of the nonlinear optical element 9 are arranged to be perpendicular to the main optical axis of the cavity and thus to the main axis of the input pump diode laser beam 2 and of the output laser beam 3. The output face of the nonlinear optical element 9 is treated to constitute a flat mirror 5 forming the output end of the cavity 1.

As discussed above, the effect of arranging the birefringent quartz plate 7 at the Brewster angle relative to the main longitudinal optical axis of the cavity 1 is that the interface between the quartz plate 7 and the amplifying element 6, and the interface between the quartz plate 7 and the optically isotropic element 8, will act as polarising elements. The effect of this then is that the cavity 1 is provided with two Lyot filters that can act to filter wavelengths within the cavity 1.

As is known in the art, a Lyot filter is formed by having a birefringent material sandwiched between two polarising elements. Thus in the laser cavity 1 of the technology described herein, by arranging the birefringent element 7 at the Brewster angle such that its surfaces act as polarising elements, two Lyot filters can be provided. The first such Lyot filter is provided as the light traverses the angled birefringent element 7 (since its surfaces act as polarising elements sandwiching the birefringent element 7 itself). The second Lyot filter is formed by virtue of the light travelling the path from the angled birefringent element 7 to the mirror 5 at the output end of the cavity and then returning to the angled birefringent element 7. In this case, the interface between the angled birefringent element 7 and the optically isotropic element 8 serves as the polarising elements for the Lyot filter effectively sandwiching the birefringent nonlinear optical element 9 which acts as the birefringent element in the second Lyot filter.

Thus, a first Lyot filter is formed by the angled birefringent element 7, and a second Lyot filter is formed by the combination of the angled birefringent element 7, the isotropic element 8, the birefringent nonlinear optical element 9, the mirror 5 at the output end of the cavity 1, the nonlinear optical element 9, the optically isotropic element 8, and the angled birefringent element 7.

The first Lyot filter is arranged to be a coarser filter that selects (filters) wavelengths within the main emission band of the amplifying element 6. The second Lyot filter is then configured to select a single wavelength from within that emission band.

The first (coarser) Lyot filter is accordingly configured to have a free spectral range of the order of magnitude of the width of the laser emission band of the amplifying element 6, and the second Lyot filter is configured to have a free spectral range that will select the desired output wavelength (frequency) from that emission band. Providing two Lyot filters in this manner can facilitate more sensitive and accurate filter tuning and wavelength selection (and make it, e.g., easier to select the desired wavelength for the laser).

In order for the second Lyot filter to select the desired wavelength from the laser emission band of the amplifying element 6, its FSR should be larger than the laser emission band width, AvG, of the amplifying element 6. This requirement limits the length of the birefringent nonlinear optical element 9 to a maximum of lₘₐₓ=c/2ΔnΔvG, where c is the speed of light.

As well as the arrangement of the angled birefringent element 7 at a particular angle relative to the longitudinal axis of the cavity 1, in the present embodiment the cavity 1 is also constructed such that the polarisation axes 11, 12 of the two birefringent elements within the cavity have particular orientations. This is illustrated in FIGS. 2 and 3.

FIG. 2 shows the orientation of the polarisation axis 11 of the angled birefringent quartz element 7. As shown in FIG. 2, the quartz plate 7 is arranged such that its polarisation axis is at 45°±0.1° relative to the main polarisation axis of the laser cavity 1. Similarly, as shown in FIG. 3, the nonlinear optical element 9 is oriented such that its polarisation axis 12 is again at 45°±0.1° to the main polarisation axis.

The elements of the cavity 1 are optically in contact with each other and joined together to form a linear, monolithic resonant laser cavity. The joining can be done using any suitable (optical) joining, e.g., bonding, technique. This allows a particularly compact and stable cavity to be constructed.

As shown in FIG. 1, apart from the faces of the angled birefringent element (and the corresponding faces of the elements that are bonded to the angled birefringent element 7), all the other faces of the elements in the laser cavity 1 are arranged to be perpendicular to the main longitudinal optical axis 10 of the cavity 1. The elements that are not bonded to the angled birefringent element 7 are in the form of crystals with parallel faces that are parallel to a tolerance of ≦20 arcsec.

When constructed in this manner, the laser cavity of the technology described herein can have a particularly compact shape and size. In the arrangement shown in FIG. 1, the cavity 1 may, for example, conveniently have dimensions of 3×3×12 mm.

In general, the Applicants have found that the laser cavity can have a size of not more than 25×20×25 mm (H×W×L) (depending upon exactly how many elements are included in the cavity). This correspondingly then facilitates constructing a diode-pumped solid state laser having a size no greater than 40×40×80 mm (final manufactured footprint).

The cavity 1 is configured such that it can provide an optical output power ≧100 mW (of 100-500 mW), a relatively high quality laser beam (a single longitudinal mode (SLM), low noise, polarised, circular beam), and is able to provide one or more of the following output laser wavelengths: 553 nm, 556 nm, 558 nm, and 561 nm.

In operation of the cavity 1 shown in FIGS. 1 to 3, as will be appreciated by those skilled in the art, a laser beam 2 emitted by a pump laser diode will be incident on the Nd:YAG amplifying crystal 6 perpendicular to the mirror 4. This will then excite the Nd:YAG crystal 6 to generate a laser beam according to the transitions of the neodymium ions which will then oscillate between the mirror faces 4 and 5 forming the resonant lasing cavity 1. (The diode laser that is used to pump the amplifying element of the laser cavity can be any suitable and desired such diode laser, such as an 808 nm IR diode laser (e.g. an 808 nm wavelength infra red GaAlAs diode laser).)

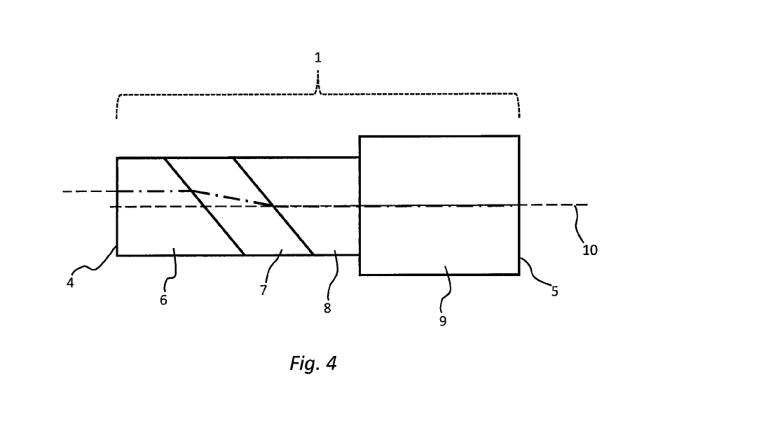

As it passes through the cavity, the laser beam within the cavity will experience a deflection at each face of the angled birefringent element 7 such that the laser beam leaving the angled birefringent element 7 will be parallel to the laser beam that entered the angled birefringent 7 (and thus parallel to the longitudinal, main optical axis, of the lasing cavity 1). As all the other interfaces in the cavity are perpendicular (orthogonal) to this longitudinal axis of the cavity, the laser beam within the cavity 1 will essentially travel parallel to the longitudinal, main axis of the cavity. This is illustrated in FIG. 4.

The nonlinear optical element 9 will act, as is known in the art, to generate second harmonic wavelengths of the laser beam produced by the amplifying element 6, which harmonic wavelength laser beam 3 is then output from the cavity 1 via the output end face 5 of the cavity. (The cavity 1 accordingly has input and output faces which are mutually parallel but perpendicular (orthogonal) to the input laser beam 2 from the pump laser diode and to the output laser beam 3 exiting from the cavity 1.)

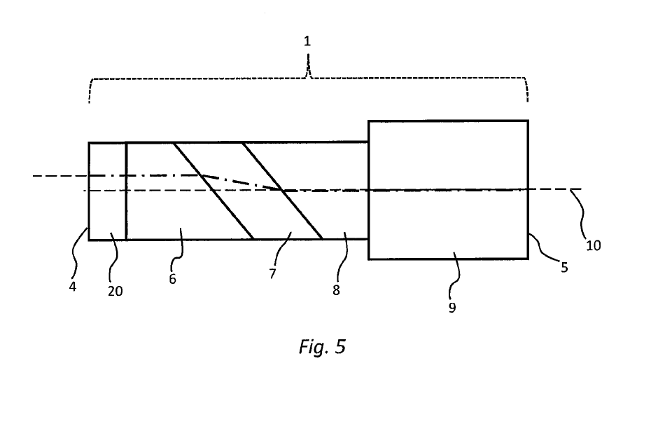

FIGS. 5, 6 and 7 show alternative embodiments for the configuration of the laser cavity 1. These embodiments include all the elements of the laser cavity shown in FIG. 1 (and arranged in the corresponding manner), but also include some additional elements.

In the embodiment shown in FIG. 5, an optically isotropic and passive element 20 is arranged at the input end of the cavity. This element 20 may be formed from any suitably optically isotropic passive medium, such as a YAG crystal. It should, as shown in FIG. 5, have parallel faces which are perpendicular to the main optical axis of the cavity 1.

This element 20 can be used to facilitate thermal management (e.g. cooling) of the amplifying element, thereby, for example, permitting higher powers to be used.

This arrangement of the cavity 1 may conveniently have dimensions of 3×3×14.5 mm.

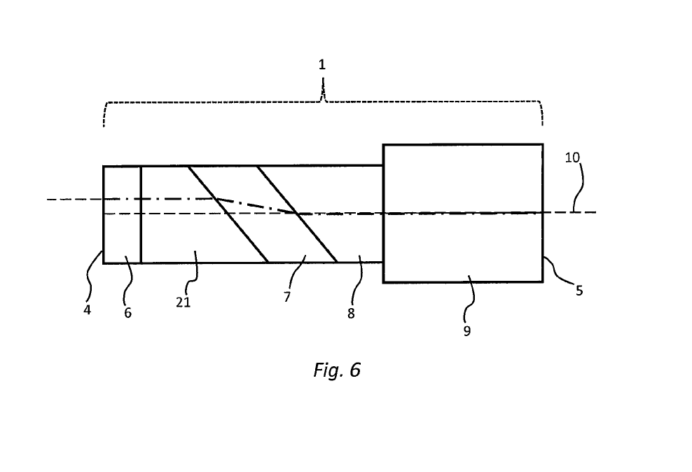

FIG. 6 shows another embodiment in which instead of the angled birefringent element 7 being sandwiched between the optically active gain element 6 and the optically isotropic element 8, it is sandwiched between two optically isotropic and passive elements 21, 8. The additional optically isotropic element 21 at the input side of the angled birefringent element 7 is in an embodiment constructed from the same material as the optically isotropic element 8 at the output side of the angled birefringent element 7, and thus in an embodiment comprises a YAG crystal. By having the angled birefringent element 7 sandwiched between two identical optically isotropic elements, manufacture of the laser cavity 1 may be easier, as the angled birefringent element 7 will be bonded to two similar materials.

This arrangement of the cavity may conveniently have dimensions of 3×3×14.5 mm.

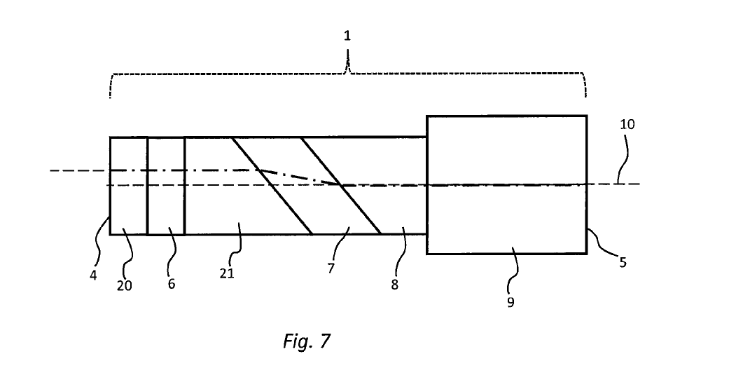

FIG. 7 shows an embodiment which combines the arrangements of FIGS. 5 and 6. Thus the arrangement for the cavity 1 shown in FIG. 7 comprises an optically isotropic and passive element 20 at its input, followed by the lasing gain element 6, followed by an optically isotropic and passive element 21, followed by the angled birefringent element 7, followed by the optically isotropic element 8 and finally the nonlinear optical element 9 at the output end of the cavity 1.

This arrangement of the cavity may conveniently have dimensions of 3×3×17 mm.

The construction methods used for the technology described herein can include and use any suitable and desired manufacturing techniques. Thus, for example, the individual elements making up the cavity may be individually formed and then appropriately bonded together, e.g., using epoxy-free optical bonding, to form a monolithic, linear, laser cavity of the form of the present embodiments. The mirrors forming the ends of the cavity are in an embodiment formed by appropriately treating the input and output faces, respectively, of the end elements of the cavity to provide suitably mirrored surfaces.

Other arrangements would, of course, be possible.

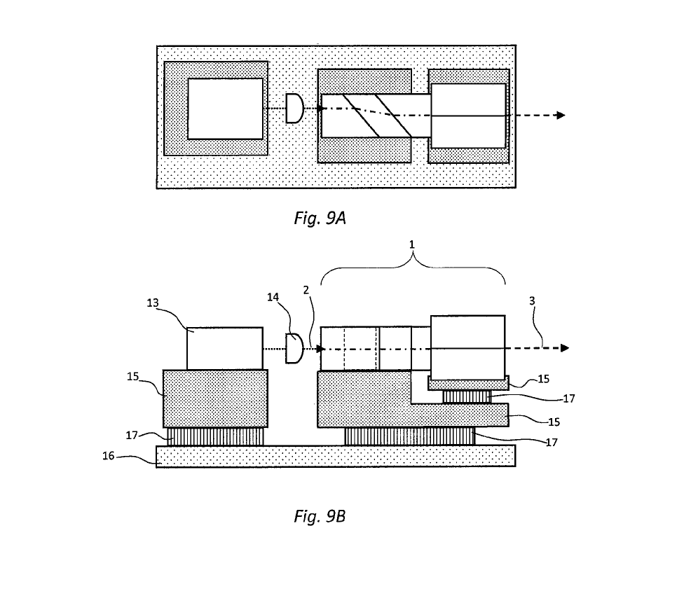

FIG. 9A shows schematically a top view and FIG. 9B shows schematically a side view of a laser constructed using the laser cavity of FIG. 1 of the technology described herein. The laser cavity 1 is coupled to one or more heat sinks 15, each of which is coupled to a temperature controller 17, such as a thermo-electric cooler. In this embodiment, the angled birefringent element and the nonlinear optical element are each provided with a separate heat sink 15 and temperature controller 17 arrangement so that their temperatures may be controlled independently of each other. The laser diode 13 used to pump the laser cavity 1 may also be provided with a separate heat sink 15 and temperature controller 17 arrangement.

The laser beam emitted by the laser diode 13 is coupled to the laser cavity 1 using a focussing lens 14.

The laser can be operated in the normal manner for a diode-pumped solid state laser. Thus, the diode laser is used to pump the amplifying element of the laser cavity so as to cause the amplifying element to generate light of a given wavelength, and the laser light output from the cavity is directed to a desired target.

The temperature of the angled birefringent element and of the nonlinear optical element are controlled independently of each other, to tune (independently of each other) the operation of the respective Lyot filters formed by these elements, for example to correct in use for any errors in the filter properties due to manufacturing tolerances.

The present embodiments can be used whenever and wherever a diode-pumped solid state laser sources or source is required, for example for laser-based fluorescent instruments, microscopy applications, etc.

It can be seen from the above that the technology described herein, in its embodiments at least, can provide a particularly compact diode-pumped solid state laser cavity and laser but which can provide reliable and accurate (and in its embodiments at least, tuneable) wavelength filtering.

This is achieved by providing within the cavity a birefringent element arranged at an angle to the main optical axis of the cavity such that its surfaces within the cavity act as polarising elements thereby to, in combination with the other elements in the cavity, provide a pair of Lyot filters within the cavity that can act as wavelength filters.

The foregoing detailed description has been presented for the purposes of illustration and description. It is not intended to be exhaustive or to limit the technology to the precise form disclosed. Many modifications and variations are possible in the light of the above teaching. The described embodiments were chosen in order to best explain the principles of the technology and its practical application, to thereby enable others skilled in the art to best utilise the technology in various embodiments and with various modifications as are suited to the particular use contemplated. It is intended that the scope be defined by the claims appended hereto.

What is claimed is:

1. A monolithic laser cavity for use in a diode-pumped solid state laser, the laser cavity comprising:
a pair of mirrors, one mirror forming an input end of the cavity for receiving an input pump laser beam in use, and the other mirror forming an output end of the cavity from which the output laser beam produced by the cavity will exit the cavity in use;
and, arranged between the mirrors forming the ends of the cavity:
an amplifying element comprising a lasing gain material that can be pumped by a diode laser to generate a laser beam;
a birefringent element having two parallel surfaces arranged after the amplifying element;
an optically isotropic element arranged after the birefringent element; and
a birefringent nonlinear optical element arranged after the optically isotropic element for frequency doubling a laser beam generated by the amplifying element so as to generate a laser beam of a second harmonic wavelength; and wherein:
the birefringent element is arranged at an angle to the optical axis of the cavity such that the parallel surfaces of the birefringent element act as polarising elements, and such that the birefringent element will accordingly act as a first Lyot filter within the laser cavity, and the angled birefringent element, the birefringent nonlinear optical element and cavity mirror following the birefringent nonlinear optical element will together act as a second Lyot filter within the laser cavity, thereby to provide wavelength selection within the laser cavity.

2. A monolithic laser cavity as claimed in claim 1, wherein the cavity consists of a mirror, followed by the amplifying element, followed by the angled birefringent element, followed by the optically isotropic element, followed by the nonlinear optical element, followed by the mirror at the end of the cavity, wherein the angled birefringent element is sandwiched between the amplifying element and the optically isotropic element.

3. A monolithic laser cavity as claimed in claim 1, wherein the laser cavity comprises: a mirror followed by an optically isotropic element, followed by the amplifying element, followed by the angled birefringent element, followed by an optically isotropic element, followed by the nonlinear optical element, followed by the mirror at the end of the cavity, wherein the angled birefringent element is sandwiched between the amplifying element and the second optically isotropic element.

4. A monolithic laser cavity as claimed in claim 1, wherein the laser cavity comprises: a mirror followed by the amplifying element, followed by an optically isotropic element, followed by the angled birefringent element, followed by an optically isotropic element, followed by the nonlinear optical element, followed by the mirror at the end of the cavity, wherein the angled birefringent element is sandwiched between the two optically isotropic elements.

5. A monolithic laser cavity as claimed in claim 1, wherein the laser cavity comprises: a mirror followed by an optically isotropic element, followed by the amplifying element, followed by an optically isotropic element, followed by the angled birefringent element, followed by an optically isotropic element, followed by nonlinear optical element, followed by the mirror at the end of the cavity, wherein the angled birefringent element is sandwiched between the second two optically isotropic elements.

6. A monolithic laser cavity as claimed in claim 1, wherein the elements that the birefringent element is sandwiched between have similar refractive indices.

7. A monolithic laser cavity as claimed in claim 1, wherein the angled birefringent element has the form of a plate.

8. A monolithic laser cavity as claimed in claim 1, wherein the first Lyot filter is configured to have a free spectral range of the order of magnitude of the width of the laser emission band of the amplifying element, and wherein the second Lyot filter is configured to have a free spectral range that will select the desired wavelength from within that emission band.

9. A monolithic laser cavity as claimed in claim 1, wherein the amplifying element is formed from Nd:YAG or Er:YAG.

10. A monolithic laser cavity as claimed in claim 1, wherein the angled birefringent element is formed from YVO₄ or quartz.

11. A monolithic laser cavity as claimed claim 1, wherein the optically isotropic element is formed from YAG or fused silica.

12. A monolithic laser cavity as claimed in claim 1, wherein the birefringent nonlinear optical element is formed from KTP, LBO, BBO or BiBO.

13. A diode-pumped solid state laser comprising a diode laser and a monolithic laser cavity as claimed in claim 1, wherein the diode laser and laser cavity are configured such that the diode laser can be used to pump the amplifying element of the laser cavity to thereby generate a laser beam output from the laser cavity.

14. A diode-pumped solid state laser as claimed in claim 13, further comprising a first temperature controller coupled to the angled birefringent element, and a second temperature controller coupled to the nonlinear optical element.

15. A diode-pumped solid state laser as claimed in claim 13, further comprising a third temperature controller coupled to the diode laser.

16. A method of operating the diode-pumped solid state laser of claim 13, the method comprising:
using the diode laser to pump the amplifying element of the laser cavity so as to cause the amplifying element to generate light of a given wavelength; and
directing the laser light output from the cavity to a desired target.

17. A method of operating a diode-pumped solid state laser as claimed in claim 16, further comprising controlling the temperatures of the birefringent element and the nonlinear optical element independently of one another.

18. A method of operating a diode-pumped solid state laser as claimed in claim 16, further comprising controlling the temperature of the diode laser independently of the temperatures of the birefringent element and/or the nonlinear optical element.

19. A method of constructing a monolithic laser cavity for use in a diode-pumped solid state laser, comprising:
providing a pair of mirrors to form the ends of the laser cavity, one mirror forming an input end of the cavity for receiving an input pump laser beam in use, and the other mirror forming an output end of the cavity from which the output laser beam produced by the cavity will exit the cavity in use; and
arranging between the mirrors forming the ends of the cavity:
an amplifying element comprising a lasing gain material that can be pumped by a diode laser to generate a laser beam;
a birefringent element having two parallel surfaces after the amplifying element;
an optically isotropic element after the birefringent element; and
a birefringent nonlinear optical element after the optically isotropic element for frequency doubling a laser beam generated by the amplifying element so as to generate a laser beam of a second harmonic wavelength; and further comprising:
arranging the birefringent element at an angle to the optical axis of the cavity such that the parallel surfaces of the birefringent element act as polarising elements, and such that the birefringent element will accordingly act as a first Lyot filter within the laser cavity, and the angled birefringent element, the birefringent nonlinear optical element and cavity mirror following the nonlinear optical element will together act as a second Lyot filter within the laser cavity, thereby to provide wavelength selection within the laser cavity; and
joining the elements of the cavity together so as to form a monolithic laser cavity.
